(19) United States
(12) Patent Application Publication
(10) Pub. No.: US 2021/0018555 A1
(43) Pub. Date: Jan. 21, 2021

(54) METHOD FOR DETERMINING AT LEAST TWO EQUIVALENT INSULATION RESISTANCES OF AN ELECTRIC SYSTEM

(71) Applicant: IFP Energies nouvelles, Rueil-Malmaison (FR)

(72) Inventors: Najla HAJE OBEID, RUEIL-MALMAISON (FR); Alexandre BATTISTON, RUEIL-MALMAISON (FR)

(21) Appl. No.: 17/040,858

(22) PCT Filed: Feb. 27, 2019
(86) PCT No.: PCT/EP2019/054866

§ 371 Date: Sep. 23, 2020

(30) Foreign Application Priority Data
Mar. 23, 2018 (FR) 1852530

(51) Int. Cl. G01R 31/14; B60L 15/20; B60L 50/60; B60L 53/20

(52) U.S. Cl. CPC G01R 31/14; B60L 15/20; B60L 50/60; B60L 2210/10; B60L 2210/20; B60L 2210/30; B60L 2210/40; B60L 53/20

(57) ABSTRACT

The present invention is a method of determining at least two equivalent insulation resistances for an electric system including a power source (2), an inverter (11), an electric load (3) and a measurement circuit (5). Measurements are performed during operation of the electric system, when the controlled switches of inverter (11) are in a zero sequence. The present invention also relates to a control system implementing same.

### CROSS-REFERENCE TO RELATED APPLICATIONS

Reference is made to International Application No. PCT/EP2019/054866, filed Feb. 27, 2019, which claims priority to French Patent Application No. 18/52.530, filed Mar. 23, 2018, the contents of which are incorporated herein by reference in their entirety.

### BACKGROUND OF THE INVENTION

### Field of the Invention

The present invention relates to the field of electric system monitoring. The invention relates in particular to the determination of the insulation resistance of an electric system.

### Description of the Prior Art

In modern manufacturing practices, integrated monitoring systems have become essential to ensure the safety of users and equipment.

For example, in the field of electric powertrains, to ensure the operational safety of an inverter—electric machine system and to ensure user safety, the insulation resistance needs to be regularly measured on the battery side (generally high voltage) and on the electric machine side, notably of its windings (coils). The purpose of these measurements is to limit electrical hazards, notably short-circuits or electrocution. There is therefore a strong interest in developing monitoring capability integrated into the system.

As regards the electric machine, it is necessary to measure the insulation resistance in any non-isolated system (galvanic isolation for example) whose source voltage is above 48V. This measurement allows detecting phase-to-ground (or phase-to-chassis) insulation faults and it plays an important part in protecting people.

Insulation resistance monitoring is also required between the battery side power connectors (positive and negative terminals) and the ground-chassis.

The devices currently available on the industrial market for insulation resistance measurement on the battery side (generally high voltage (above 120 Vdc)) and on the machine side (notably its windings) are independent of the machine control system. They are known as insulation monitoring devices. These systems are not integrated into the electric system and they therefore require shutting off the electric system for installing the insulation monitoring device and performing measurements.

Furthermore, various insulation resistance measurement methods and systems have been developed.

### BACKGROUND OF THE INVENTION

For example, patent application EP-2,413,148 relates to a circuit for measuring the insulation resistance that is not influenced by the battery voltage. This measurement circuit is suitable only for determining the insulation resistance of a battery, but it does not allow determining an insulation resistance for a complete electric system (comprising a battery, an inverter and an electric load). Therefore this measurement circuit does not allow locating a possible insulation fault in an electric system. The measurement methods presented in US published patent applications 2003/0,234,653 and 2015/042,350 have the same limitations.

U.S. Pat. No. 7,554,336 discloses a method for measuring the insulation resistance of an electric circuit. For this method, one of the measurements is performed offline, which is described as a state wherein all the switches of the inverter are open. This is not a common case for a converter control, and it requires modifying the inverter control device. Access to the inverter control is therefore necessary to insert these states.

Furthermore, this circuit is complex and it is limited to computer networks (IT).

US published patent application 2012/223,734 describes an insulation resistance measurement method applied to photovoltaic panels. This method uses a specific instrument for measuring the insulation resistance. Thus, this document does not describe a measuring device that can be embedded, which is useful notably for electric powertrain applications.

Patent application WO-2013/124,571 describes a method and a system for estimating the insulation resistance between a battery and an electric ground. This method requires applying a voltage to carry out the measurements, which is restrictive and limits the use of the battery while measuring.

### SUMMARY OF THE INVENTION

To overcome these drawbacks, the present invention relates to a method of determining at least two equivalent insulation resistances for an electric system including a power source (a battery for example), an inverter, an electric load (an electric machine for example) and a measurement circuit. The measurements are performed during operation of the electric system, when the controlled switches of the inverter are in a zero sequence, which allows implementing the method during operation of the electric system. Such a method is suitable for determining the insulation resistance of an electric system and it makes it possible to locate a possible insulation fault within the electric system.

The present invention also relates to a control system implementing the method.

The invention relates to a method of determining at least two equivalent insulation resistances for an electric system including a power source, an energy converter and an electric load, the energy converter comprising a switching branches, each of the switching branches comprising two controlled switches, the electric system further including a measurement circuit added between the positive terminal of the electric source and the ground or the chassis of the electric system, the measurement circuit comprising a shunt resistor (Rshunt) in series with a controlled switch. For this method, the following steps are earned out:
a) when the controlled switches of the energy converter are in zero sequence, two voltages ere measured in parallel with the measurement circuit, the first voltage V_{pt_0} being measured with the controlled switch of the measurement circuit in an open position, and the second voltage V_{pt_1} being measured with the controlled switch of the measurement circuit in a closed position; and
b) the equivalent insulation resistances of the electric system are determined by use of the measured voltages V_{pt_0} and V_{pt_1}.

According to an embodiment of the invention, the controlled switches of the energy converter are controlled by a pulse width modulation method.

According to an implementation, four equivalent insulation resistances are determined by repeating steps a) and b) for each zero sequence of the control of the controlled switches of the energy converter.

Advantageously, an equivalent insulation resistance R_{_iso_h}⁺ is determined between the positive terminal of the power source and the chassis or the ground of the electric system for the zero sequence for which the controlled switches of the energy converter connected to the positive terminal of the power source are in closed position by use of an equation:

$${R}_{\_ iso {\_ h}^{+}} = {R}_{\_ shunt} [ \frac{{V}_{pt \_ h 0}}{{V}_{batt} - {V}_{pt \_ h 0}} \frac{{V}_{batt} - {V}_{pt \_ h 1}}{{V}_{pt \_ h 1}} - 1 ] ,$$

with R_{_shunt} being the shunt resistance, V_{batt} being the voltage of the electrical power source, V_{pt_h0} being the first voltage measured for the zero sequence and V_{pt_h1} being the second voltage measured for the zero sequence.

Advantageously, an equivalent insulation resistance R_{_iso_h}⁻ is determined between the negative terminal of the electrical power source and the chassis or the ground of the electrical system for the zero sequence for which controlled switches of the energy converter connected to the positive terminal of the power source are in a closed position by using an equation:

$${R}_{\_ iso {\_ h}^{-}} = \frac{{R}_{\_ iso {\_ h}^{+}} \times {R}_{\_ shunt}}{{R}_{\_ iso {\_ h}^{+}} + {R}_{\_ shunt}} ( \frac{{V}_{batt}}{{V}_{pt \_ h 1}} - 1 ) ,$$

with R_{_shunt} being the shunt resistance, V_{batt} being the voltage of the power source and V_{pt_h1} being the second voltage measured for this zero sequence.

According to an aspect of the invention an equivalent insulation resistance R_{_iso_b}⁺ is determined between the positive terminal of the electrical power source and the chassis or the ground of the electrical system for the zero sequence for which the controlled switches of the energy converter connected to the negative terminal of the power source are in closed position using an equation:

$${R}_{\_ iso {\_ b}^{+}} = {R}_{\_ shunt} [ \frac{{V}_{pt \_ b 0}}{{V}_{batt} - {V}_{pt \_ b 0}} \frac{{V}_{batt} - {V}_{pt \_ b 1}}{{V}_{pt \_ b 1}} - 1 ] ,$$

with R_{_shunt} being the shunt resistance, V_{batt} being the voltage of the power source, V_{pt_b0} being the first voltage measured for the zero sequence and V_{pt_b1} being the second voltage measured for this zero sequence.

Preferably, an equivalent insulation resistance R_{_iso_b}⁻ is determined between the negative terminal of the power source and the chassis or the ground of the electrical system for the zero sequence for which controlled switches of the inverter connected to the negative terminal of the power source are in closed position by use of an equation:

$${R}_{\_ iso {\_ b}^{-}} = \frac{{R}_{\_ iso {\_ b}^{+}} \times {R}_{\_ shunt}}{{R}_{\_ iso {\_ b}^{+}} + {R}_{\_ shunt}} ( \frac{{V}_{batt}}{{V}_{pt \_ b 1}} - 1 ) ,$$

with R_{_shunt} being the shunt resistance, V_{batt} being the voltage of the power source and V_{pt_b1} being the second voltage measured for the zero sequence.

According to an embodiment, the equivalent insulation resistances are compared with a threshold in order to determine a possible insulation fault within the electric system.

Advantageously, the possible insulation fault is located by the following conditions:
i) if all the equivalent resistances are above the threshold, then there is no insulation fault of the electric system;
ii) if only equivalent resistances R_{_iso_h}⁺ and R_{_iso_b}⁻ are below the threshold, then the insulation fault is located on a side of the electric load;
iii) if only equivalent resistances R_{_iso_h}⁺ and R_{_iso_b}⁺ are below the threshold, then the insulation fault is located on a side of the positive terminal of the power source;
iv) if only equivalent resistances R_{_iso_h}⁻ and R_{_iso_b}⁻ are below the threshold, then the insulation fault is located on a side of the negative terminal of the power source;
v) if only equivalent resistances R_{_iso_h}⁺, R_{_iso_b}⁺ and R_{_iso_b}⁻ are below the threshold, then insulation faults are located on a side of the positive terminal of the power source and on a side of the electric load;
vi) if only equivalent resistances R_{_iso_h}⁺, R_{_iso_h}⁻ and R_{_iso_b}⁻ are below the threshold, then insulation faults are located on a side of the negative terminal of the power source and on a side of the electric load; and
vii) if all the equivalent resistances are below the threshold, then insulation faults are located on a side of the positive and negative terminals of the electrical power source.

According to an aspect, the threshold S is determined with a formula: S=α×V_{batt}, with α being a safely coefficient and V_{batt} being the voltage of the power source, and preferably the value of safely coefficient α is 1000Ω/V.

Furthermore, the invention relates to a system for controlling an electric system in order to determine at least two equivalent insulation resistances of the electric system, the electric system including a power source, an energy converter, an electric load and a measurement circuit, the inverter comprising a plurality of switching branches, each of the switching branches comprising two controlled switches, the measurement circuit comprising a shunt resistor in series with a controlled switch added between the positive terminal of the power source and the ground or the chassis of the electric system. The control system is configured to implement the method according to one of the above features.

According to an embodiment, the electric load is an electric machine and the power source is an electric battery.

Furthermore, the invention relates to a use of a control system according to one of the above features for controlling a powertrain of an electric or hybrid vehicle.

### BRIEF DESCRIPTION OF THE DRAWINGS

Other features and advantages of the method according to the invention will be clear from reading the description hereafter of embodiments given by way of non-limitative example, with reference to the accompanying figures wherein:

FIG. 1 illustrates an electric system equipped with a measurement circuit suited for implementing the method according to an embodiment of the invention; and

FIG. 2 illustrates the voltage acquisition times according to an embodiment of the invention.

### DETAILED DESCRIPTION OF THE INVENTION

The present invention relates to a method of determining at least two equivalent insulation resistances of an electric system.

Insulation resistance is understood to be the electrical resistance of isolation or insulation between an electric system and its outside medium (generally air between the electric system and its housing). This insulation resistance represents the resistance formed between the electric system and the ground (case of a stationary electric system), or between the electric system and its chassis (case of an embedded electric system of electric vehicle type). Knowledge of this value allows determining of an insulation fault in an electric system. Such an insulation fault can generate safety problems for an electric system.

The insulation resistance is referred to as equivalent because it depends on the structure of the measurement circuit, in particular on the shunt resistor (the measurement circuit is described in the rest of the description).

The electric system according to the invention includes a power source, an energy converter and an electric load.

The power source provides electrical energy and it can be an electric battery providing a continuous supply of electrical energy.

The energy converter allows electrical energy conversion. For example, an energy converter makes it possible to convert an alternating voltage to another alternating voltage with a different frequency and/or amplitude, it is then referred to as an alternating/alternating or AC/AC converter. According to another example, an energy converter makes it possible to convert an alternating voltage to a direct voltage which it is then referred to as a rectifier, an alternating/direct or AC/DC converter. For the reverse direct/alternating conversion, it is referred to as DC/AC converter or inverter. According to a last example, an energy converter can convert a direct voltage to a direct voltage of different voltage which it is then referred to as a DC/DC converter. Converters can be reversible or non-reversible. Generally, conversion is performed by use of controlled switches distributed among (generally a multiple of three) switching branches. Each switching branch comprises two opposite controlled switches which when the first controlled switch is open, the second controlled switch of the some branch is closed, and vice versa.

The electric load designates any system using electrical energy. It can be an electric machine, a resistive load, an electrical network, etc.

According to a preferred embodiment of the invention, the electric system comprises a battery, a three-branch DC/AC inverter and a three-phase electric machine.

Furthermore, the electric system comprises a measurement circuit. In other words, the measurement circuit is included in the electric system. The measurement circuit is used and controlled to determine the equivalent insulation resistances. Thus, determining insulation resistances can be done without any specific equipment (sensor for example) external to the electric system.

The measurement circuit is added between the positive terminal of the power source and the ground or the chassis of the electric system.

The measurement circuit comprises a shunt resistor in series with a controlled switch. The value of the shunt resistance can range between 500 kΩ and 5 MΩ.

According to an aspect of the invention, all the controlled switches (that is of the energy converter and of the measurement circuit) can be switches of MOSFET (Metal Oxide Semiconductor Field Effect Transistor) and/or IGBT (Insulated Gate Bipolar Transistor) type, and/or of any other similar technology.

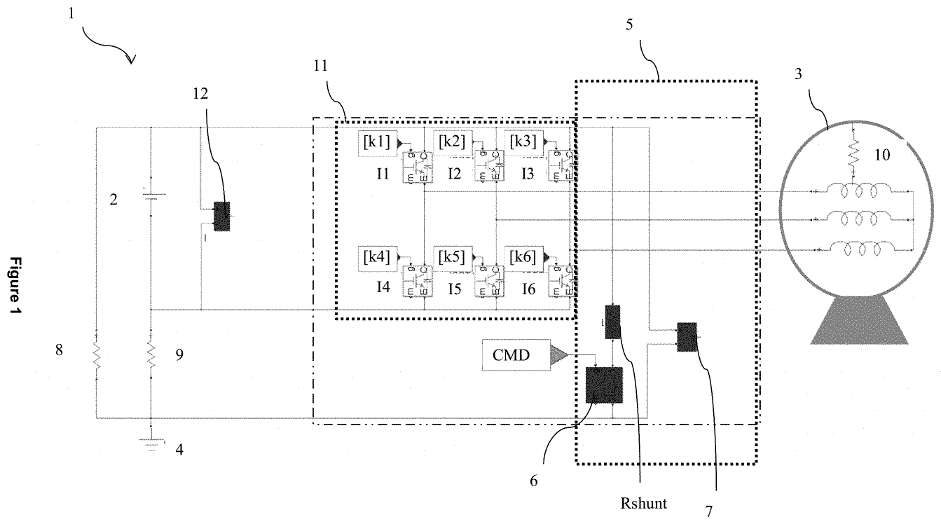

FIG. 1 schematically illustrates, by way of non-limitative example, an electric circuit suited to the method according to an embodiment of the invention. Electric circuit 1 includes a power source 2 (an electric battery here), an inverter 11 (energy converter), an electric load 3 (a three-phase electric machine here) and a measurement circuit 5.

Inverter 11 has three switching arms with each switching arm having two controlled switches I1 to I6 in series. Each controlled switch comprises a control [k1] to [k6]. The first branch of inverter 11 comprises switches I1 and I4, control [k4] of switch I4 being opposite control [k1] of switch I1 (I4 is open when I1 is closed, and vice versa). The second branch of inverter 11 comprises switches I2 and I5, control [k5] of switch I5 being opposite control [k2] of switch I2. The third branch of inverter 11 comprises switches I3 and I6, control [k6] of switch I6 being opposite control [k3] of switch I3.

Measurement circuit 5 is arranged between the positive terminal of power source 2 and the ground or the chassis 4 of electric system 2. Measurement circuit 5 comprises a combination in series of a shunt resistor Rshunt with a controlled switch 6. Control CMD of controlled switch 6 allows controlled switch 6 to be opened and closed. Measurement circuit 5 further comprises means or measurement device (7) for measuring the voltage at the terminals of measurement circuit 5.

Moreover, FIG. 1 shows insulation resistances 8, 9 and 10. Insulation resistance 8 is located between the positive terminal of power source 2 and the ground or chassis 4 of the electric system. Insulation resistance 9 is located between the negative terminal of power source 2 and the ground or chassis 4 of electric system 1. Insulation resistance 10 is located between electric load 3 and the ground or chassis 4 of the electric system.

FIG. 1 further illustrates means or measurement device 12 for measuring the voltage of power source 2.

The method according to the invention comprises the following steps:
a) when the controlled switches of the inverter are in zero sequence, two voltages are measured with the voltages being measured in parallel with the measurement circuit. The first voltage is measured by opening the controlled switch of the measurement circuit, and the second voltage is measured by closing the controlled switch of the measurement circuit, and
b) the equivalent insulation resistances of the electric system are determined by use of the measured voltages.

The zero sequence of the inverter control corresponds to the times of the inverter control when no differential current passes between the power source and the electric load. The power taken from the source is therefore zero during these sequences. A first zero sequence is thus obtained when the controlled switches of the inverter connected to the positive terminal of the power source are all closed. A second zero sequence is obtained when the controlled switches of the inverter connected to the negative terminal of the power source are all closed.

For the example of FIG. 1, the first zero sequence corresponds to the closing of controlled switches I1, I2 and I3 (I4, I5 and I6 being open), and the second zero sequence corresponds to the closing of controlled switches I4, I5 and I6 with I1, I2 and I3 being open.

The method according to the invention does not modify the control of the controlled switches of the inverter, and uses existing specific sequences of the inverter control to perform the measurements. The method according to the invention only controls the controlled switch of the measurement circuit in order to carry out two voltage measurements. It is thus possible to use the method according to the invention during operation of the electric system since the electric system does not need to be shut off in order to determine the insulation resistances.

Furthermore, the method according to the invention does not require modifying the inverter.

Moreover, the invention allows insulation resistance determination on an ad hoc basis, online and in real time.

Preferably, the controlled switches of the inverter are controlled by a PWM (Pulse Width Modulation) method. The general principle of this modulation method is that, by applying a succession of discrete states during well selected periods of time, any intermediate value con be obtained on average over a certain period of time.

According to an embodiment of the invention, equivalent insulation resistances are determined for each zero sequence of the control of the controlled switches of the inverter. Steps a) and b) described above are therefore repeated for the two zero sequences. Two voltage measurements are thus obtained for the first zero sequence, as well as two voltage measurements for the second zero sequence. These four voltages allow to determine four equivalent insulation resistances, which enables precise location of an insulation fault of the electric circuit.

In order to carry out the measurements at the time of a zero sequence of the control of the inverter, the method according to the invention can comprise a step of detecting the zero sequences.

For example, this detection can be achieved by measuring a current in the electric system, or in a predictive manner, by knowing the future states of the control of the controlled switches of the inverter.

According to an aspect of the invention, the method can comprise a step of measuring the voltage at the terminals of the power source. This voltage of the power source can be used for step b) of determining the equivalent insulation resistances.

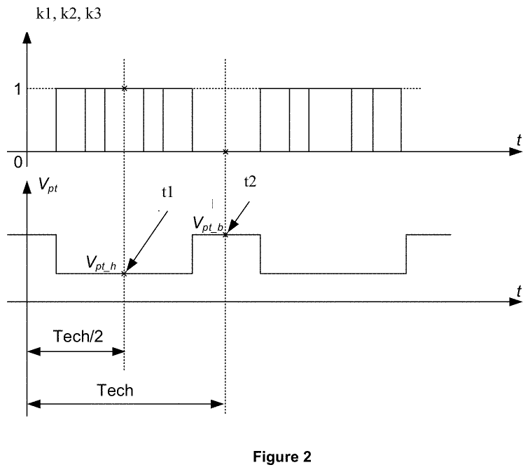

FIG. 2 illustrates the measurement times of the method according to an embodiment of the invention, for the electric system example illustrated in FIG. 1. The top graph schematically shows, but is not limited to, controls k1, k2 and k3 for a pulse width modulation method (the curves of controls k1, k2 and k3 are illustrated in the same reference frame). Value 1 of these controls corresponds to the closing of the corresponding controlled switches, and value 0 of these controls corresponds to the opening of the corresponding controlled switches. The bottom graph schematically shows, but is not limited to, the voltage measured at the terminals of the measurement circuit. At time t1, there is a first zero sequence (k1=k2=k3=1), the first two voltage measurements denoted by V_{pt_h0} (when the controlled switch of the measurement circuit is open) and V_{pt_h1} (when the controlled switch of the measurement circuit is closed) can thus be carried out. At time t2, there is a second zero sequence (k1=k2=k3=0, therefore k4=k5=k6=1), two other voltage measurements denoted by V_{pt_b0} (when the controlled switch of the measurement circuit is open) and V_{pt_b1} (when the controlled switch of the measurement circuit is closed) can thus be carried out.

Furthermore, FIG. 2 shows that, in order to determine the equivalent insulation resistances, it is possible to acquire the voltage at the terminals of the measurement circuit at two different times spaced apart by Tech/2 (Tech represents the sampling period of the pulse width modulation method).

Step b) of determining the equivalent insulation resistances can be carried out by applying conventional laws of electricity, notably Ohm's law, the mesh rule and the nodal rule.

According to an aspect of the invention, step b) of determining the equivalent insulation resistances can be carried out by use of the calculator of the energy converter (the inverter for example). Alternatively, this step can be carried out by use of a dedicated calculator.

According to a first embodiment, two equivalent insulation resistances R_{_iso_h}⁺ and R_{_iso_h}⁻ can be determined for the zero sequence where the controlled switches of the inverter connected to the positive terminal of the power source are in closed position (in the case of FIGS. 1 and 2, this corresponds to k1=k2=k3=1).

For this embodiment, an equivalent insulation resistance R_{_iso_h}⁺ can be determined between the positive terminal of the power source and the chassis or the ground of the electric system for the zero sequence where the controlled switches of the inverter connected to the positive terminal of the power source are in closed position by use of an equation:

$${R}_{\_ iso {\_ h}^{+}} = {R}_{\_ shunt} [ \frac{{V}_{pt \_ h 0}}{{V}_{batt} - {V}_{pt \_ h 0}} \frac{{V}_{batt} - {V}_{pt \_ h 1}}{{V}_{pt \_ h 1}} - 1 ] ,$$

with R_{_shunt} being the shunt resistance, V_{batt} being the voltage of the power source, V_{pt_h0} being the first voltage measured for the zero sequence and V_{pt_h1} being the second voltage measured for the zero sequence.

Furthermore, an equivalent insulation resistance R_{_iso_h}⁻ can be determined between the negative terminal of the power source and the chassis or the ground of the electric system for the zero sequence for which controlled switches of the inverter connected to the positive terminal of the power source are in a closed position by using an equation:

$${R}_{\_ iso {\_ h}^{-}} = \frac{{R}_{\_ iso {\_ h}^{+}} \times {R}_{\_ shunt}}{{R}_{\_ iso {\_ h}^{+}} + {R}_{\_ shunt}} ( \frac{{V}_{batt}}{{V}_{pt \_ h 1}} - 1 ) ,$$

with R_{_shunt} being the shunt resistance, V_{batt} being the voltage of the power source and V_{pt_h1} being the second voltage measured for this zero sequence.

According to a second embodiment, two equivalent insulation resistances R_{_iso_b}⁺ and R_{_iso_b}⁻ can be determined can be determined for the zero sequence where the controlled switches of the inverter connected to the negative terminal of the power source are in closed position (in the case of FIGS. 1 and 2, this corresponds to k4=k5=k6=1; therefore with k1=k2=k3=0).

For this embodiment, an equivalent resistance R_{_iso_b}⁺ can be determined between the positive terminal of the power source and the chassis or the ground at the electric system for the zero sequence where the controlled switches of the inverter connected to the negative terminal of the power source are in closed position by use of an equation:

$${R}_{\_ iso {\_ b}^{+}} = {R}_{\_ shunt} [ \frac{{V}_{pt \_ b 0}}{{V}_{batt} - {V}_{pt \_ b 0}} \frac{{V}_{batt} - {V}_{pt \_ b 1}}{{V}_{pt \_ b 1}} - 1 ] ,$$

with R_{_shunt} being the shunt resistance. V_{batt} being the voltage of the power source, V_{pt_b0} being the first voltage measured for this zero sequence and V_{pt_b1} being the second voltage measured for this zero sequence.

Furthermore, an equivalent resistance R_{_iso_b}⁻ can be determined between the negative terminal of the power source and the chassis or the ground of the electric system for the zero sequence where the controlled switches of the inverter connected to the negative terminal of the electric source are in closed position by use of an equation:

$${R}_{\_ iso {\_ b}^{-}} = \frac{{R}_{\_ iso {\_ b}^{+}} \times {R}_{\_ shunt}}{{R}_{\_ iso {\_ b}^{+}} + {R}_{\_ shunt}} ( \frac{{V}_{batt}}{{V}_{pt \_ b 1}} - 1 ) ,$$

with R_{_shunt} being the shunt resistance, V_{batt} being the voltage of the power source and V_{pt_b1} being the second voltage measured for the zero sequence.

Advantageously, the two embodiments described above can be combined (with voltage measurements for the two zero sequences). In this cease, four equivalent insulation resistances R_{_iso_h}⁺, R_{_iso_h}⁻, R_{_iso_b}⁺ and R_{_iso_b}⁻ are determined. Obtaining the four equivalent insulation resistances allows precise detection of a possible insulation fault.

According to an implementation of the invention, the method can comprise a step of comparing the equivalent insulation resistances which have been determined with a threshold. This comparison with a threshold allows determination of the existence of an insulation fault in the electric system. Moreover, this comparison allows locating a possible insulation fault in the electric system. Preferably, all the equivalent insulation resistances that are determined can be compared with the same threshold, to facilitate detection and location of a possible insulation fault.

Comparison threshold S can be determined with a formula S=α×V_{batt}, with α being a safety coefficient and V_{batt} being the voltage of the power source. Preferably the value of safety coefficient α can be 1000Ω/V; indeed with this value generally being provided in electrical safety standards.

For the embodiment wherein the four equivalent insulation resistances described above are determined, a possible insulation fault is located by use of the following conditions:
i) if all the equivalent resistances are above the threshold, then there is no insulation fault of the electric system;
ii) if only equivalent resistances R_{_iso_h}⁺ and R_{_iso_b}⁻ are below the threshold, then the insulation fault is located on a side of the electric load;
iii) if only equivalent resistances R_{_iso_h}⁺ and R_{_iso_b}⁺ are below the threshold, then the insulation fault is located on a side of the positive terminal of the power source,
iv) if only equivalent resistances R_{_iso_h}⁻ and R_{_iso_b}⁻ are below the threshold, then the insulation fault is located on a side of the negative terminal of the power source;
v) if only equivalent resistances R_{_iso_h}⁺, R_{_iso_b}⁺ and R_{_iso_b}⁻ are below the threshold, then insulation faults are located on a side of the positive terminal of the power source and on a side of the electric load;
vi) if only equivalent resistances R_{_iso_h}⁺, R_{_iso_h}⁻ and R_{_iso_b}⁻ are below the threshold, then insulation faults are located on a side of the negative terminal of the power source and on a side of the electrical load; and
vii) if all the equivalent resistances are below the threshold, then insulation faults are located on a side of the positive and negative terminals of the electrical power source.

Thus, the method according to the invention provides precise location of an insulation fault, which allows improved safety and replacing only the defective elements, without having to replace the entire electric circuit.

Furthermore, the invention relates to a system for controlling an electric system, the control system being configured to determine at least two equivalent insulation resistances of the electric system, and preferably four equivalent insulation resistances.

The electric system according to the invention includes a power source, an energy converter (an inverter for example) and an electric load.

The power source provides electrical energy and can be an electric battery.

The energy converter allows electrical energy conversion. For example, an energy converter makes it possible to convert an alternating voltage to another alternating voltage with a different frequency and/or amplitude which then is referred to as an alternating/alternating or AC/AC converter. According to another example, an energy converter makes possible conversion of an alternating voltage to a direct voltage which then is referred to as a rectifier, an alternating/direct or AC/DC converter. For the reverse direct/alternating conversion, it is referred to as DC/AC converter or inverter. According to a last example, an energy converter can convert a direct voltage to a direct voltage of different voltage which then is referred to as a DC/DC converter. Converters can be reversible or non-reversible. Generally, conversion is performed by controlled switches distributed among (generally a multiple of three) switching branches. Each switching branch comprises two opposite controlled switches which when the first controlled switch is open, the second controlled switch of the same branch is closed, and vice versa.

The electric load designates any system using electrical energy and can be an electric machine, a resistive load, an electrical network, etc.

According to a preferred embodiment of the invention, the electric system comprises a battery, a three-branch DC/AC inverter and a three-phase electric machine.

Moreover, the electric system comprises a measurement circuit. The measurement circuit is used and controlled to determine the equivalent insulation resistances. In other words, the measurement circuit is included in the electric system. Thus, determining insulation resistances can be done without any specific equipment external to the electric system.

The measurement circuit is added between the positive terminal of the power source and the ground or the chassis of the electric system.

The measurement circuit comprises a shunt resistor in series with a controlled switch. The value of the shunt resistance can range between 500 kΩ and 5 MΩ.

According to the invention, the control system is configured to implement the determination method according to any one of the variant combinations described above.

In particular, the control system controls the controlled switch of the measurement circuit and performs the voltage measurements at the terminals of the measurement circuit. The control system performs no specific control of the controlled switches of the inverter to determine the equivalent insulation resistances with the control of the controlled switches of the inverter being unchanged, for example by use of a pulse width modulation method).

The invention also relates to the use of the method and the control system for controlling an electric powertrain of a vehicle, in particular an electric or hybrid vehicle.

However, the method and the control system according to the invention are suited for any embedded or stationary application.

1-13. (cancelled)

14. A method of determining at least two equivalent insulation resistances for an electrical system including an electrical power source, an energy converter and an electric load, the energy converter comprising switching branches, each of the switching branches comprising two controlled switches, the electric system further including a measurement circuit between a positive terminal of the electrical power source and ground or a chassis of the electrical system and the measurement circuit comprising a shunt resistor in series with a controlled switch, the method comprising steps of:
a) when controlled switches of the energy converter are in a zero sequence, measuring two voltages in parallel with the measurement circuit, a first voltage being measured with the controlled switch of the measurement circuit being in an open position, and a second voltage being measured with the controlled switch of the measurement circuit in closed position; and
b) determining the equivalent insulation resistances of the electrical system by using of the measured voltages.

15. The method as claimed in claim 14, wherein the controlled switches of the energy converter are controlled by pulse width modulation.

16. The method as claimed in claim 14, wherein four equivalent insulation resistances are determined by repeating steps a) and b) for each zero sequence of control of the controlled switches of the energy converter.

17. A method as claimed in claim 14, wherein an equivalent insulation resistance R_{_iso_h}⁺ is determined between a positive terminal of the electrical power source and the chassis or the ground of the electrical system for a zero sequence for which the controlled switches of the energy converter are connected to the positive terming of the electrical power source are in a closed position by using an equation:
$${R}_{\_ iso {\_ h}^{+}} = {R}_{\_ shunt} [ \frac{{V}_{pt \_ h 0}}{{V}_{batt} - {V}_{pt \_ h 0}} \frac{{V}_{batt} - {V}_{pt \_ h 1}}{{V}_{pt \_ h 1}} - 1 ] ,$$
with R_{_shunt} being the shunt resistance, V_{batt} being the voltage of the electrical power source, V_{pt_h0} being the first voltage measured for the zero sequence and V_{pt_h1} being the second voltage measured for the zero sequence.

18. The method as claimed in claim 17, wherein an equivalent insulation resistance R_{_iso_h}⁻ is determined between the negative terminal of the electrical power source and the chassis or the ground of the electrical system for the zero sequence for which controlled switches the energy converter are connected to the positive terminal of the electrical power source are in closed position by using an equation:
$${R}_{\_ iso {\_ h}^{-}} = \frac{{R}_{\_ iso {\_ h}^{+}} \times {R}_{\_ shunt}}{{R}_{\_ iso {\_ h}^{+}} + {R}_{\_ shunt}} ( \frac{{V}_{batt}}{{V}_{pt \_ h 1}} - 1 ) ,$$
with R_{_shunt} being the shunt resistance, V_{batt} being the voltage of the power source and V_{pt_h1} being the second voltage measured for the zero sequence.

19. The method as claimed in claim 14, wherein an equivalent insulation resistance R_{_iso_b}⁺ is determined between the positive terminal of the electrical power source and the chassis or the ground of the electrical system for the zero sequence for which the controlled switches of the energy converter are connected to the negative terminal of the electrical power source are in closed position using an equation:
$${R}_{\_ iso {\_ b}^{+}} = {R}_{\_ shunt} [ \frac{{V}_{pt \_ b 0}}{{V}_{batt} - {V}_{pt \_ b 0}} \frac{{V}_{batt} - {V}_{pt \_ b 1}}{{V}_{pt \_ b 1}} - 1 ] ,$$
with R_{_shunt} being the shunt resistance, V_{batt} being the voltage of the power source, V_{pt_b0} being the first voltage measured for the zero sequence and V_{pt_b1} being the second voltage measured for this zero sequence.

20. A method as claimed in claim 19, wherein an equivalent insulation resistance R_{_iso_b}⁻ is determined between the negative terminal of the electrical power source and the chassis or the ground of the electrical system for a zero sequence for which controlled switches of the inverter connected to the negative terminal of the electrical power source are in closed position by using an equation:
$${R}_{\_ iso {\_ b}^{-}} = \frac{{R}_{\_ iso {\_ b}^{+}} \times {R}_{\_ shunt}}{{R}_{\_ iso {\_ b}^{+}} + {R}_{\_ shunt}} ( \frac{{V}_{batt}}{{V}_{pt \_ b 1}} - 1 ) ,$$
with R_{_shunt} being the shunt resistance, V_{batt} being the voltage of the electrical power source and V_{pt_b1} being the second voltage measured for the zero sequence.

21. A method as claimed in claim 14, wherein the equivalent insulation resistances are compared with a threshold to determine a possible insulation fault within the electrical system.

22. A method as claimed in claim 17, wherein the possible insulation fault is located by use of the following conditions:
i) if all the equivalent resistances are above the threshold, then there is no insulation fault of the electrical system;
ii) if only equivalent resistances R_{_iso_h}⁺ and R_{_iso_b}⁻ are below the threshold, then the insulation fault is located on a side of the electrical load;
iii) if only equivalent resistances R_{_iso_h}⁺ and R_{_iso_b}⁺ are below the threshold, then the insulation fault is located on a side of the positive terminal of the electrical power source;
iv) if only equivalent resistances R_{_iso_h}⁻ and R_{_iso_b}⁻ are below the threshold, then the insulation fault is located on a side of the negative terminal of the electrical power source;
v) if only equivalent resistances R_{_iso_h}⁺, R_{_iso_b}⁺ and R_{_iso_b}⁻ are below the threshold, then insulation faults are located on a side of the positive terminal of the electrical power source and on a side of the electric load;
vi) if only equivalent resistances R_{_iso_h}⁺, R_{_iso_h}⁻ and R_{_iso_b}⁻ are below the threshold, then insulation faults are located on a side of the negative terminal of the electrical power source and on a side of the electrical load; and
vii) if all the equivalent resistances are below the threshold, then insulation faults are located on a side of the positive and negative terminals of the electrical power source.

23. A method as claimed in claim 21, wherein a threshold S is determined with a formula: S=α×V_{batt}, with α being a safety coefficient and V_{batt} being a voltage of the electrical power source, with a value of a safety coefficient α being 1000Ω/V.

24. A system for controlling an electrical system for determining at least two equivalent insulation resistances of the electrical system, the electrical system including a power source, an energy converter, an electrical load and a measurement circuit, the inverter comprising switching branches, each of the switching branches comprising two controlled switches, the measurement circuit comprising a shunt resistor in series with a controlled switch between a positive terminal of the power source and the ground or the chassis of the electrical system, and wherein the control system is configured to implement the method as claimed in claim 14.

25. A control system as claimed in claim 24, wherein the electrical load is an electrical machine and the electrical power source is an electrical battery.

26. A use of a control system as claimed in claim 25 comprising:
controlling a powertrain of an electrical or hybrid vehicle.
